(19) United States
(12) Patent Application Publication
(10) Pub. No.: US 2015/0125978 A1
(43) Pub. Date: May 7, 2015

(54) Method For Increasing Heat Conductivity In Systems That Use High Power Density LEDs

(71) Applicant: PRINTABLED S.R.L., Montecchio Emilia (Reggio Emilia) (IT)

(72) Inventor: Massimiliano Dal Pont, Seren del Grappa (Belluno) (IT)

(21) Appl. No.: 14/398,382

(22) PCT Filed: Apr. 29, 2013
(86) PCT No.: PCT/IB2013/053386

§ 371 Date: Oct. 31, 2014

(30) Foreign Application Priority Data
May 2, 2012 (IT) MO2012A000116

(51) Int. Cl. H01L 33/64; H01L 25/075

(52) U.S. Cl. CPC H01L 33/644; H01L 25/0753; H01L 2933/0075
USPC 438/28

(57) ABSTRACT

There is provided a method for improving heat dissipation in systems that use LEDs with high power density mounted on a printed circuit board, the LEDs each being provided, on a face thereof, with a plurality of electrical contacts for connecting electrically the LEDs to conducting tracks made on the board, and with a heat dissipating element, the board including a substrate made of heat-conducting material, covered by a layer of electrically insulating material, on which the conducting tracks are made, the LEDs being mounted on the board in such a manner that the face with the heat dissipating element faces the layer of electrically insulating material, the method including the steps of removing the material of the electrically insulating layer at a contact zone between the heat dissipating element of each LED and the electrically insulating layer; and making a heat-conducting connection between the heat dissipating element and substrate.

The invention relates to a method for improving the dissipation of heat produced in systems that use LEDs with high power density, for example devices for drying inks in printing apparatuses that use UV LEDs.

High power density LEDs are defined as LEDs with power density above 50 W/cm².

In the aforesaid systems the problem of dissipating the heat produced by the LEDs during operation is critical, inasmuch as the temperature of the system must be prevented from increasing excessively, which could irremediably damage the LEDs.

In known prior-art systems, as shown in FIG. 2, the LEDs 1 are mounted on a printed circuit board 2 that comprises a thermally conductive substrate 3, made, for example, of aluminium or copper, having, for example, a thickness comprised between about 1 and 2 mm. The substrate 3 is covered by a layer 4 of electrically insulating material, having, for example, a thickness of about 100 μm, on which tracks of electrically conductive material (not shown) are obtained to which the electrical contacts 5 of the LEDs 1 are connected.

The heat produced by the LEDs during operation is dispersed through the substrate 3, which can be cooled by a suitable cooling device (not shown).

The presence of the layer 4 of electrically insulating material nevertheless hinders the dissipation of heat because even electrically insulating materials that have the best thermal conductivity features have too high thermal resistance, such as to cause a temperature increase at the junction between the LED 1 and the layer of insulating material 4 of even 40-50° C. and beyond, which entails a significant increase in the steady-state operating temperature of the LEDs, with a consequent risk of rapid damage to the LEDs, or anyway a significant decrease in the life of the LEDs.

The present invention proposes to provide a method for improving the dissipation of the heat in systems that use LEDs with high power density, in such a manner that the steady-state operating temperature of the LEDs can be lowered simply and effectively.

The task that is the basis of the present invention is achieved with a method according to claim 1.

Owing to the invention, heat transmission from the LEDs to the substrate 3 of the printed circuit board 2 is improved significantly, so that the heat produced by the operation of the LEDs can be dissipated much more rapidly and efficiently through the substrate 3, thus significantly lowering the steady-state operating temperature of the LEDs.

One manner of implementing the invention will now be disclosed by way of purely and non-limiting example, with reference to the attached drawings, in which:

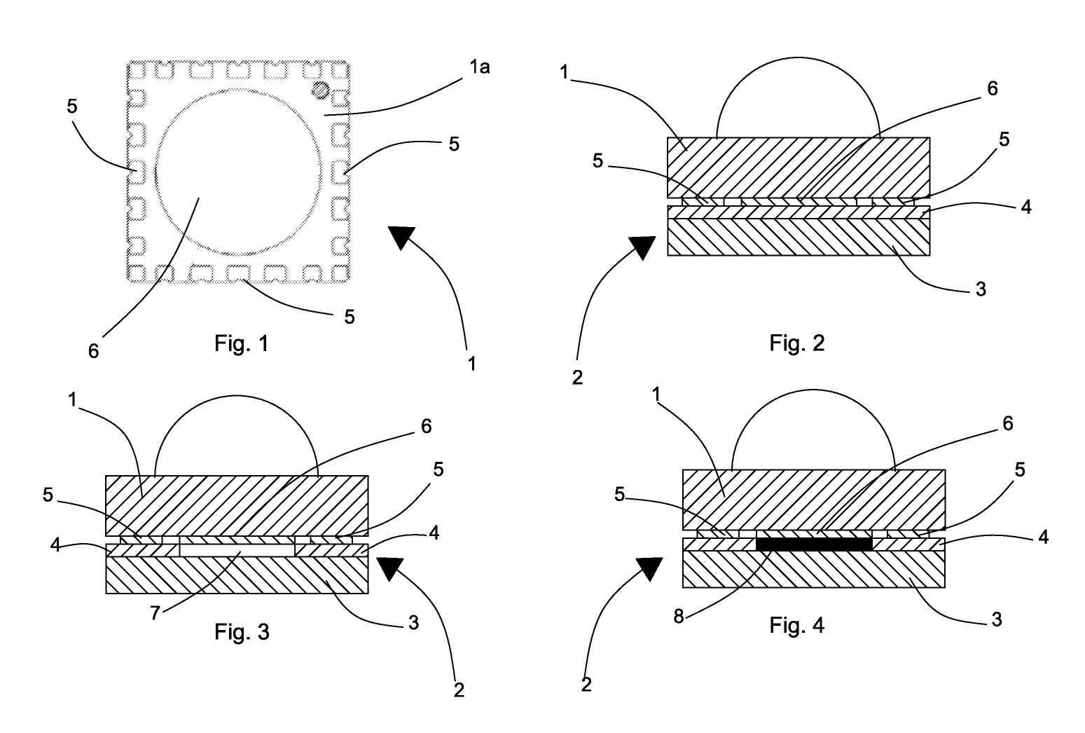

FIG. 1 is a bottom view of a LED having a high specific power;

FIG. 2 is a cross section of the LED in FIG. 1 mounted on a printed circuit board, according to the state of the art;

FIG. 3 is a cross section like the one in FIG. 2 that illustrates a first step of the method according to the present invention;

FIG. 4 is a cross section like the one in FIG. 2 that illustrates a second step of the method according to the present invention.

The LED 1 is provided, in the lower part 1a thereof, with a series of electrical contacts 5 that are used to connect the LED 1 to an electric circuit. In the lower part 1a the LED 1 also has a heat dissipating element 6, a so-called thermal slug, or thermal pad, made, for example, of a metal material that is a good heat conductor. The heat dissipating element 6 promotes the passage of heat produced by the LED during operation thereof to the substrate 3 of the printed circuit board 2. The heat dissipating element is insulated electrically from the electrical contacts 5.

However, as already said, the layer 4 of electrically insulating material that covers the substrate 3 hinders the aforesaid passage of heat.

According to the present invention, in order to improve heat transmission between the LED 1 and the substrate 3, there is provided removing the material of a part of the electrically insulating layer 4, for example by controlled z-axis milling, at a contact zone 7 between the heat dissipating element 6 and the electrically insulating layer 4, so as to make it possible to make, in said zone, a connection 8 with high thermal conductivity between the heat dissipating element 6 and the substrate 3. The connection with high thermal conductivity can be obtained by welding the heat dissipating element 6 to the substrate 3, with a heat-conducting material as weld material, for example metal material. Alternatively, the connection between the heat dissipating element 6 and the substrate 3 can be obtained by making a covering with heat-conducting material, for example metal material, on the heat dissipating element 6 and/or on the substrate 3 for example by an electrochemical method or by depositing vapours of said metal material on said heat dissipating element 6 and/or on said substrate 3.

Owing to the connection 8 with high thermal conductivity between the heat dissipating element 6 and the substrate 3 the transmission to the substrate 3 of the heat produced by the LED 1 during operation thereof is greatly improved, which enables the operating temperature of the LED 1 to be noticeably reduced, thus significantly increasing the working life thereof and drastically reducing the risk of faults due to overheating of the LED.

In the practical embodiment, the materials, dimensions and constructional details can be different from those indicated but be technically equivalent thereto, without thereby falling outside the scope of this invention.

1. A method for improving heat dissipation in systems that use LEDs with high power density mounted on a printed circuit board, said LEDs each being provided, on a face thereof, with a plurality of electrical contacts usable for connecting electrically the LEDs to conducting tracks made on said board, said LEDs being also provided, on said face, with a heat dissipating element, said board comprising a substrate made of heat-conducting material, covered by a layer of electrically insulating material, on which said conducting tracks are made, said LEDs being mounted on said board in such a manner that said face with said heat dissipating element faces said layer of electrically insulating material, wherein said method comprises the following steps:
removing the material of a part of said electrically insulating layer at a contact zone between said heat dissipating element of each LED and said electrically insulating layer;
making a heat conducting connection between said heat dissipating element and said substrate.

2. The method according to claim 1, wherein said heat conducting connection is made by using a metal material.

3. The method according to claim 1, wherein said heat conducting connection is made by welding said heat dissipating element to said substrate.

4. The method according to claim 1, wherein said heat conducting connection is obtained by making a covering of a heat conducting material on said heat dissipating element and/or on said substrate.

5. The method according to claim 4, wherein said covering is made by an electrochemical method.

6. The method according to claim 4, wherein said covering is made by deposing vapours of said heat conducting material on said heat dissipating element and/or on said substrate.

7. The method according to claim 2, wherein said heat conducting connection is made by welding said heat dissipating element to said substrate.

8. The method according to claim 2, wherein said heat conducting connection is obtained by making a covering of a heat conducting material on said heat dissipating element and/or on said substrate.
